(19) United States
(12) Patent Application Publication
(10) Pub. No.: US 2007/0026573 A1
(43) Pub. Date: Feb. 1, 2007

(54) Method of making a stacked die package

(76) Inventors: Aminuddin Ismail, Selangor (MY); Wai Yew Lo, Petaling Jaya (MY); Kong Bee Tiu, Pandamaran (MY); Cheng Choi Yong, Puchong (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/193,144

(22) Filed: Jul. 28, 2005

(51) Int. Cl. H01L 21/00; H01L 21/44

(52) U.S. Cl. 438/118; 438/124; 438/617; 257/E23.127

(57) ABSTRACT

A method of making a stacked die package (50) includes attaching and electrically connecting a first integrated circuit (IC) die (52) to a base carrier (56). A plurality of successive layers (54A, 54B and 54C) of an adhesive material (54) is formed on the first die (52). A second die (72) is attached to the first die (52) with the adhesive material (54) such that the successive layers of adhesive material (54A, 54B and 54C) maintain a predetermined spacing (H) between the first die (52) and the second die (72). The second die (72) is electrically connected to the base carrier (56).

### BACKGROUND OF THE INVENTION

The present invention relates to the packaging of integrated circuits (ICs) in general and more specifically to a method of making a stacked die package.

Stacked die packages are characterised by having two or more dice stacked within a single package. The stacking of two or more dice within a single package increases the functional integration of the package, without increasing its footprint. FIG. 1 shows a conventional stacked die package 10. The package 10 includes a bottom die 12, a base carrier 14, and a top die 16. The bottom die 12 is attached to the base carrier 14 with a first adhesive layer 18. Die bonding pads (not shown) on the bottom and top dice 12 and 16 are electrically connected to the base carrier 14 with first wires 20 and second wires 22, respectively, via wirebonding. The bottom and top dice 12, 16 and the first and second wires 20, 22 are sealed with a resin 24, thus forming the stacked die package 10. As can be seen from FIG. 1, a sufficiently large spacing is required between the bottom and top dice 12, 16 to prevent damage to the first wires 20 when the top die 16 is attached to the bottom die 12. Accordingly, the conventional practice has been to use a spacer 26, which is typically a blank silicon die to allow adequate spacing between the bottom and top dice 12 and 16. The spacer 26 is attached to the bottom die 12 with a second adhesive layer 28, and the top die 16 is subsequently attached to the spacer 26 with a third adhesive layer 30. While the use of blank silicon dies in stacked die packages addresses the problem of damage to the first wires 20 when stacking the top die 16, it increases process lead time and manufacturing cost.

In view of the foregoing, it would be desirable to have an inexpensive method of making a stacked die package that does not require a blank silicon die.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a conventional stacked die package;

FIG. 2 is an enlarged cross-sectional view of a first or bottom die having a plurality of adhesive material layers formed thereon in accordance with an embodiment of the present invention;

FIG. 3 is an enlarged cross-sectional view of the bottom die of FIG. 2 including a second or top die;

FIG. 4 is an enlarged cross-sectional view of a bottom die coupled to a base carrier by reverse bonding in accordance with another embodiment of the present invention;

FIG. 5 is an enlarged cross-sectional view of the bottom die of FIG. 4 having a plurality of adhesive material layers formed thereon; and

FIG. 6 is an enlarged cross-sectional view of the bottom die and adhesive material layers of FIG. 5 having a top die stacked thereon.

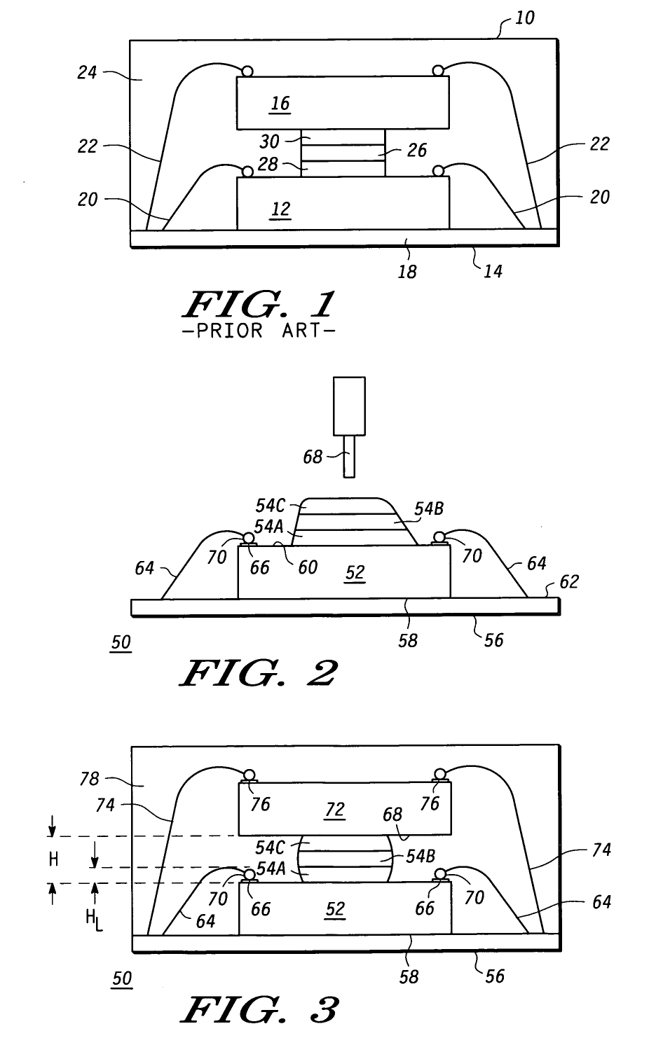

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. For simplicity, examples used to illustrate the invention refer only to a package having two stacked dice. However, the same invention in fact can be applied to packages having more than two stacked dice. In the drawings, like numerals are used to indicate like elements throughout.

The present invention provides a method of making a stacked die package including the steps of attaching and electrically connecting a first integrated circuit (IC) die to a base carrier. A plurality of successive layers of an adhesive material is formed on the first die. A second die is attached to the first die with the adhesive material such that the successive layers of adhesive material maintain a predetermined spacing between the first die and the second die. The second die is electrically connected to the base carrier.

The present invention also provides a method of making a stacked die package including the step of attaching a first IC die to a base carrier, the first die having a bottom surface and a top surface. The top surface has a central area and a peripheral area. The peripheral area includes a plurality of first die bonding pads. The bottom surface of the first die is attached to a top side of the base carrier. The first die is electrically connected to the base carrier by wirebonding first wires to the first die bonding pads and to the top side of the base carrier. A plurality of successive layers of an adhesive material is formed on the central area of the top surface of the first die. A bottom surface of a second die is attached to the top surface of the first die with the adhesive material such that the successive layers of adhesive material maintain a predetermined spacing between the first die and the second die. The second die includes a plurality of second die bonding pads located on a top surface thereof. The second die is electrically connected to the base carrier by wirebonding second wires to the second die bonding pads and to the top side of the base carrier. Finally, the first and second dice, the first and second wires, and at least a portion of the base carrier are encapsulated.

The present invention further provides a method of making a stacked die package including the step of attaching a first IC die to a base carrier, the first die having a bottom surface and a top surface. The top surface has a central area and a peripheral area. The peripheral area includes a plurality of first die bonding pads. The bottom surface of the first die is attached to a top side of the base carrier. A plurality of first bumps is formed on respective ones of the first die bonding pads. The first die is electrically connected to the base carrier by reverse bonding first wires from the top side of the base carrier to the first bumps on the first die bonding pads such that a plurality of stitch bonds are formed on the first bumps. A plurality of second bumps is formed on the stitch bonds. A plurality of successive layers of an adhesive material is formed on the central area of the top surface of the first die. The first and second bumps form a wall around the peripheral area of the first die to contain the adhesive material. A bottom surface of a second die is attached to the top surface of the first die with the adhesive material such that the successive layers of adhesive material maintain a predetermined spacing between the first die and the second die. The second die includes a plurality of second die bonding pads located on a top surface thereof. The second die is electrically connected to the base carrier by wirebonding second wires to the second die bonding pads and to the top side of the base carrier. Finally, the first and second dice, the first and second wires, and at least a portion of the base carrier are encapsulated.

FIGS. 2 and 3 are enlarged cross-sectional views that illustrate a method of making a stacked die package 50 in accordance with an embodiment of the present invention.

Referring now to FIG. 2, a first or bottom integrated circuit (IC) die 52 having a plurality of successive layers 54A, 54B and 54C of an adhesive material 54 formed thereon is shown. The first die 52 is attached and electrically connected to a base carrier or substrate 56.

The first die 52 has a bottom surface 58 and a top surface 60. The top surface 60 includes a central area (not shown) and a peripheral area (not shown). The bottom surface 58 of the first die 52 is attached to a top side 62 of the base carrier 56 with an adhesive (not shown). The adhesive may be any suitable adhesive material, such as an adhesive tape, a thermo-plastic adhesive, an epoxy material, or the like. Such adhesives for attaching an IC die to a base carrier are well known to those of skill in the art.

The first die 52 is electrically connected to the base carrier 56 with first wires 64. In this particular example, the first wires 66 are wirebonded to a plurality of first die bonding pads 66 on the peripheral area of the first die 52 and to the top side 62 of the base carrier 58. Suitable bond wires typically comprise conductive metal wires, typically formed of copper or gold.

The successive layers of adhesive material 54A, 54B and 54C are formed by dispensing the adhesive material 54 in multiple applications over a central area of the first die 52. In this particular example, the adhesive material 54 is dispensed in an uncured or soft phase in multiple applications over the central area of the top surface 60 of the first die 52. After each application, the adhesive material 54 is cured through exposure and/or heating for a specified time period. The adhesive material 54 for each succeeding layer 54B and 54C is dispensed when a preceding layer 54A and 54B, respectively, is substantially cured, that is, when the adhesive material 54 making up the preceding layer 54A, 54B is in a gel-like, flexible state. The degree of cure may be controlled by adjusting the temperature at the heater block (not shown), as is known by those of skill in the art.

When fully cured, the successive layers of adhesive material 54A, 54B and 54C provide the mechanical strength required to hold a second or top die to the first die 52, as described below. The successive layers of adhesive material 54A, 54B and 54C may be formed on the first die 52 in a number of ways, such as with a needle 68 and syringe (not shown) or an epoxy dam writer, as are known by those of skill in the art. In this particular example, each layer of adhesive material 54A, 54B and 54C is between about 1.5 mils to about 2.0 mils thick. However, it should be understood that the present invention is not limited by the thickness of each layer 54A, 54B and 54C. The thickness of each layer 54A, 54B and 54C may be varied by changing the size of the needle 68 from which the adhesive material 54 is dispensed.

Although the adhesive material 54 in this particular example does not contact the first wires 64, it will be understood by those of skill in the art that the adhesive material 54 may in alternative embodiments be in contact with or cover the wirebonds 70 formed between the first wires 64 and the first bonding pads 66 first die 52, thereby reinforcing the bond therebetween. The adhesive material 54 may comprise any of the typical adhesives used to attach one die to another. Typical adhesives include epoxy, cyanate ester and polyimide. The adhesive material 54 is preferably a snap cure material, as is known by those of skill in the art.

Referring now to FIG. 3, the stacked die package 50 is shown, in which a second or top die 72 is stacked on the first die 52. More particularly, a bottom surface of the second or top die 72 is attached to the top surface 60 of the first die 52 with the adhesive material 54. The bottom surface of the second die 72 adheres to the top most layer of the adhesive material 54, which in this case is the layer 54C. The layers of the adhesive material 54A, 54B and 54C ensure adequate spacing between the first and second dice 52 and 72 to ensure that the second die 72 does not damage the electrical connection (wirebond) of the first wires 64 to the bonding pads 66.

The second die 72 is electrically connected to the base carrier 56, which provides an interconnect network for electrically connecting the first and second dice 52 and 72 to each other and to other components or devices. In this particular example, the second die 72 is electrically connected to the base carrier 56 with second wires 74, which are wirebonded to a plurality of second die bonding pads 76 located on a top surface of the second die 72 and to corresponding pads on the top side 62 of the base carrier 56. The second wires 74 preferably are of the same type as the first wires 64.

Finally, the first and second dice 52 and 70, the first and second wires 66 and 74, and at least a portion of the base carrier 56 are encapsulated with an encapsulant 78 such as resin. The encapsulation step may be done by performing a molding operation, as is known by those of skill in the art.

As previously discussed, the successive layers of adhesive material 54A, 54B and 54C maintain a predetermined spacing H between the first and second dice 52 and 72. The predetermined spacing H is sufficient to protect the electrical connections between the first die 52 and the base carrier 56, in this case, the first wires 64, from being damaged by the attachment of the second die 72 to the first die 52. In this particular example, the predetermined spacing H is at least about 5 mils. Nevertheless, those of skill in the art will understand that the present invention is not limited by the magnitude of the spacing H. Rather, the magnitude of the spacing H depends on the height of the loop HL made by the first wires 64 extending beyond the top surface 60 of the first die 52. Specifically, the spacing H must be larger than the loop height HL. For example, a spacing H of about 6 mils is required for a loop height HL of about 4 mils. Although only three (3) successive layers of adhesive material 54A, 54B and 54C are shown in FIGS. 2 and 3, those of skill in the art will understand that the present invention is not limited by the number of successive adhesive layers formed on the first die 52; there can be more or fewer layers depending on the required spacing H and the thickness of each layer.

The first die 52 and the second die 72 preferably have substantially the same length and width dimensions. However, the second die 72 may be somewhat larger or somewhat smaller than the first die 52. For example, typical first and second die sizes may range from 4 mm×4 mm to 12 mm×12 mm. The first and second dice 52, 72 may also have the same thickness, however, this is not required. Depending on the required final package outline thickness, the first and second dice 52, 72 may have a thickness ranging from about 6 mils to about 21 mils. Each of the base carrier 56, the first die 52, and second die 72 are of a type well known to those of ordinary skill in the art, and further description of these components is not required for a complete understanding of the present invention.

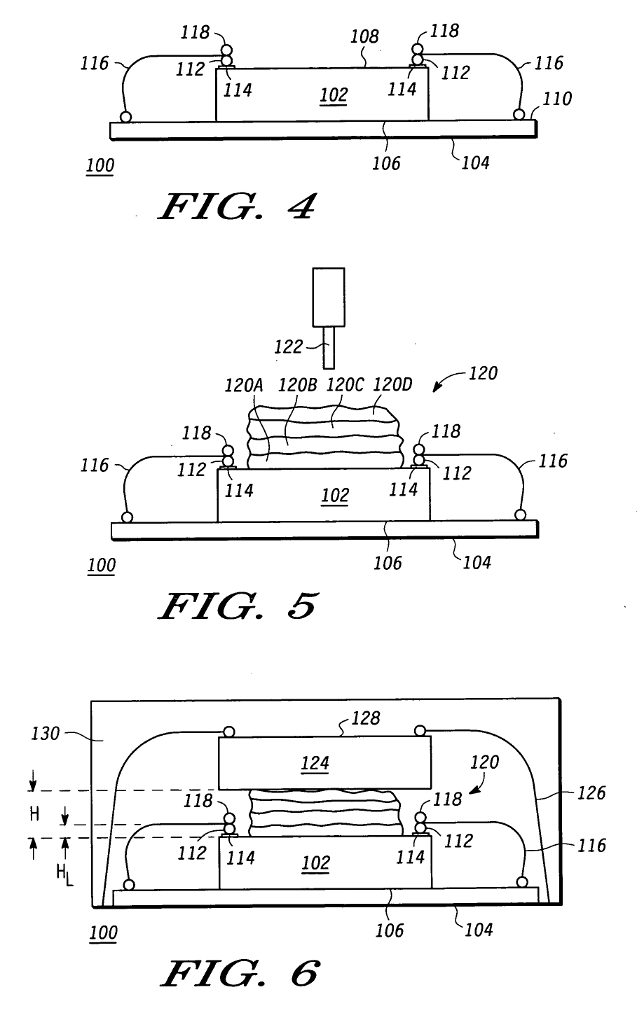

Another embodiment of the present invention will now be described with reference to FIGS. 4 to 6, which are enlarged cross-sectional views that illustrate a method of making a stacked die package 100.

Referring now to FIG. 4, a first or bottom die 102 is attached and electrically connected to a base carrier or substrate 104 by reverse bonding, as shown. The first die 102 has a bottom surface 106 and a top surface 108. The top surface 108 includes a central area (not shown) and a peripheral area (not shown). The bottom surface 106 of the first die 102 is attached to a top side 110 of the base carrier 104 with an adhesive (not shown). The adhesive may be any suitable adhesive material, such as an adhesive tape, a thermo-plastic adhesive, an epoxy material, or the like. Such adhesives for attaching an IC die to a base carrier are well known to those of skill in the art.

A plurality of first bumps 112 is formed on respective first die bonding pads 114 on the peripheral area of the first die 102. The first die 102 is electrically connected to the base carrier 104 with first wires 116. In this particular example, the first wires 116 are reverse bonded from the top side 110 of the base carrier 104 to the first bumps 112 on the first die bonding pads 114 such that a plurality of stitch bonds are formed on the first bumps 112. Suitable bond wires typically comprise conductive metal wires, such as copper or gold wires. A plurality of second bumps 118 is formed on the stitch bonds. The first and second bumps 112 and 118 form a wall around the peripheral area of the first die 102.

Referring now to FIG. 5, a plurality of successive layers 120A, 120B, 120C and 120D of an adhesive material 120 is formed on the first die 102. The successive layers of adhesive material 120A, 120B, 120C and 120D are formed by dispensing the adhesive material 120 in multiple applications over the first die 102. In this particular example, the adhesive material 120 is dispensed in an uncured or soft phase in multiple applications over the central area of the top surface 108 of the first die 102. After each application, the adhesive material 120 is at least partially cured through exposure and/or heating for a specified time period. The adhesive material 120 for each succeeding layer 120B, 120C and 120D is dispensed when a preceding layer 120A, 120B and 120C, respectively, is substantially cured, that is, when the adhesive material 120 making up the preceding layer 120A, 120B, 120C is in a gel-like, flexible state. As previously discussed, the degree of cure may be controlled by adjusting the temperature at the heater block (not shown), as is known by those of skill in the art.

When fully cured, the successive layers of adhesive material 120A, 120B, 120C and 120D provide the mechanical strength required to hold a second or top die to the first die 102, as described below. The successive layers of adhesive material 120A, 120B, 120C and 120D may be formed on the first die 102 in a number of ways, such as with a needle 122 and syringe (not shown) or an epoxy dam writer, as are known by those of skill in the art. In this particular example, each layer of adhesive material 120A to 120D is between about 1.5 mils to about 2.0 mils thick. However, it should be understood that the present invention is not limited by the thickness of each layer and that the the thickness of each layer may be varied by changing the size of the needle 122 from which the adhesive material 120 is dispensed.

The wall of first and second bumps 112 and 118 formed around the peripheral area of the first die 102 serves to contain the adhesive material 120 that is dispensed onto the central area of the first die 102. Despite gaps in the wall between the first and second bumps 112 and 118, the adhesive material 120 is nevertheless contained within the wall by capillary action because the container formed by the wall has a very small cross-sectional area. The containment of the adhesive material 120 within the wall facilitates the subsequent attachment of the second die to the first 102 die, described below.

The adhesive material 120 may comprise any of the typical adhesives used to attach one die to another. Typical adhesives include epoxy, cyanate ester and polyimide. The adhesive material 120 is preferably a snap cure material, as is known by those of skill in the art.

Referring now to FIG. 6, the stacked die package 100 is shown. A bottom surface of a second or top die 124 is attached to the top surface 108 of the first die 102 with the adhesive material 120. More particularly, the second die 124 is adhered to the topmost layer 120D of the adhesive material 120. The second die 124 is then electrically connected to the base carrier 104, which provides an interconnect network for electrically connecting the first and second dice 102 and 124 to each other and to other components or devices. In this particular example, the second die 124 is electrically connected to the base carrier 104 with second wires 126, which are wirebonded to a plurality of second die bonding pads (not shown) on a top surface 128 of the second die 124 and to the top side of the base carrier 104. Finally, the first and second dice 102 and 124, the first and second wires 116 and 126, and at least a portion of the base carrier 104 are encapsulated with an encapsulant 130 such as resin. Solder balls (not shown) may be attached to a bottom surface of the substrate 104, thereby forming a BGA package, as is known in the art. Alternatively, the substrate 104 may comprise a lead frame flag area such that QFN type packages are formed. The packaged devices 100 may be formed one at a time or many at a time, such as via an array, that is via a molded array process (MAP).

As previously discussed, the successive layers of adhesive material 120A to 120D maintain a predetermined spacing H between the first and second dice 102 and 124. The predetermined spacing H is sufficient to protect the electrical connections between the first die 102 and the base carrier 104, in this case, the first wires 116, from being damaged by the attachment of the second die 124 to the first die 102. In this particular example, the predetermined spacing H is at least about 5 mils. Nevertheless, those of skill in the art will understand that the present invention is not limited by the magnitude of the spacing H. As previously discussed, the spacing H must be larger than the height HL of the loop made by the first wires 114 extending beyond the top surface 108 of the first die 102. Further, although only four (4) successive layers of adhesive material 120A, 120B, 120C and 120D are shown in FIGS. 4 to 6, those of skill in the art will understand that the present invention is not limited by the number of successive adhesive layers formed on the first die 102; there can be more or fewer layers depending on the required spacing H and the thickness of each layer.

Moreover, as previously discussed, the first and second dice 102 and 124 preferably have substantially the same length and width dimensions. However, the second die 124 may be somewhat larger or somewhat smaller than the first die 102. For example, typical first and second die sizes may range from 4 mm×4 mm to 12 mm×12 mm. The first and second dice 102, 124 may also have the same thickness, however, this is not required. Depending on the required final package outline thickness, the first and second dice 102, 124 may have a thickness ranging from about 6 mils to about 21 mils. Each of the base carrier 104, the first die 102, and second die 124 are of a type well known to those of ordinary skill in the art, and further description of these components is not required for a complete understanding of the present invention.

While a method of making a stacked die package has been described, the present invention further is a stacked die package, including a base carrier having a top side and a bottom side; a first integrated circuit (IC) die attached and electrically connected to the base carrier, the first die having a bottom surface and a top surface, the top surface having a central area and a peripheral area, wherein the bottom surface of the first die is attached to the top side of the base carrier; a plurality of successive layers of an adhesive material formed on the central area of the top surface of the first die; a second IC die having a bottom surface attached to the top surface of the first die with the adhesive material, wherein the successive layers of adhesive material maintain a predetermined spacing between the first die and the second die and wherein the second die is electrically connected to the base carrier.

The adhesive material may be epoxy, cyanate ester or polyimide. The adhesive material is preferably a snap cure material. The predetermined spacing is sufficient to protect the electrical connections between the first die and the base carrier from being damaged by the attachment of the second die to the first die. Each layer of adhesive material is between about 1.5 mils to about 2.0 mils thick, while the predetermined spacing is at least about 5 mils.

The first die is electrically connected to the base carrier with first wires. The first wires may be wirebonded to a plurality of first die bonding pads on the peripheral area of the first die and to the top side of the base carrier. In an alternative embodiment, the stacked die package includes a plurality of first bumps formed on the first die bonding pads on the peripheral area of the first die. First wires are reverse bonded from the top side of the base carrier to the first bumps on the first die bonding pads such that a plurality of stitch bonds are formed on the first bumps. The stacked die package includes a plurality of second bumps formed on the stitch bonds. The first and second bumps form a wall around the peripheral area of the first die to contain the adhesive material.

The second die is electrically connected to the base carrier with second wires, the second wires being wirebonded to a plurality of second die bonding pads on a top surface of the second die and to the top side of the base carrier. The first and second dice, the first and second wires, and at least a portion of the base carrier are encapsulated with an encapsulant such as resin.

The first and second dice may have substantially the same length and substantially the same width. In an alternative embodiment, the second die may be larger than the first die.

As is evident from the foregoing discussion, the present invention provides an inexpensive method of making a stacked die package by eliminating the use of a blank silicon die or a specially manufactured tape from the packaging process. The process lead time is also reduced because the step of attaching the blank silicon die or the specially manufactured tape is not required.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is not limited to a package with two stacked dice, but can be applied to a package with multiple stacked dice. Further, the present invention is not limited to any single wire bonding technique or to a particular package. That is, the invention is applicable to all wire bonded package types, including but not limited to BGA, QFN, QFP, PLCC, CUEBGA, TBGA, and TSOP. In addition, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. A method of making a stacked die package, comprising:
attaching a first integrated circuit (IC) die to a base carrier;
electrically connecting the first die to the base carrier;
forming a plurality of successive layers of an adhesive material on the first die;
attaching a second die to the first die with the adhesive material, wherein the successive layers of adhesive material maintain a predetermined spacing between the first die and the second die; and
electrically connecting the second die to the base carrier.

2. The method of making a stacked die package of claim 1, wherein the successive layers of adhesive material are formed by dispensing the adhesive material in multiple applications over the first die.

3. The method of making a stacked die package of claim 2, wherein the adhesive material for each succeeding layer is dispensed when a preceding layer is substantially cured.

4. The method of making a stacked die package of claim 3, wherein the adhesive material is one of epoxy, cyanate ester and polyimide.

5. The method of making a stacked die package of claim 4, wherein the adhesive material comprises a snap cure material.

6. The method of making a stacked die package of claim 1, wherein the predetermined spacing is sufficient to protect the electrical connections between the first die and the base carrier from being damaged by the attachment of the second die to the first die.

7. The method of making a stacked die package of claim 6, wherein the predetermined spacing is at least about 5 mils.

8. The method of making a stacked die package of claim 7, wherein each layer of adhesive material is between about 1.5 mils to about 2.0 mils thick.

9. The method of making a stacked die package of claim 1, wherein the first die is electrically connected to the base carrier with first wires.

10. The method of making a stacked die package of claim 9, wherein the first wires are wirebonded to a plurality of first die bonding pads on a peripheral area of a top surface of the first die and to a top side of the base carrier.

11. The method of making a stacked die package of claim 9, further comprising the step of forming a plurality of first bumps on respective first die bonding pads on a peripheral area of a top surface of the first die.

12. The method of making a stacked die package of claim 11, wherein the first wires are reverse bonded from a top side of the base carrier to the first bumps on the first die bonding pads such that a plurality of stitch bonds are formed on the first bumps.

13. The method of making a stacked die package of claim 12, further comprising the step of forming second bumps on the stitch bonds.

14. The method of making a stacked die package of claim 13, wherein the first and second bumps form a wall around the peripheral area of the first die to contain the adhesive material.

15. The method of making a stacked die package of claim 9, wherein the second die is electrically connected to the base carrier with second wires, the second wires being wirebonded to a plurality of second die bonding pads on a top surface of the second die and to a top side of the base carrier.

16. The method of making a stacked die package of claim 15, further comprising the step of encapsulating the first and second dice, the first and second wires, and at least a portion of the base carrier.

17. A method of making a stacked die package, comprising:
attaching a first IC die to a base carrier, the first die having a bottom surface and a top surface, the top surface having a central area and a peripheral area, the peripheral area including a plurality of first die bonding pads, wherein the bottom surface of the first die is attached to a top side of the base carrier;
electrically connecting the first die to the base carrier by wirebonding first wires to the first die bonding pads and to first corresponding pads on the top side of the base carrier;
forming a plurality of successive layers of an adhesive material on the central area of the top surface of the first die;
attaching a bottom surface of a second die to the top surface of the first die by way of the successive layers of the adhesive material, wherein the second die has a plurality of second die bonding pads located on a top surface thereof, and wherein the successive layers of adhesive material maintain a predetermined spacing between the first die and the second die;
electrically connecting the second die to the base carrier by wirebonding second wires to the second die bonding pads and to second corresponding pads on the base carrier; and
encapsulating the first and second dice, the first and second wires, and at least a portion of the base carrier.

18. The method of making a stacked die package of claim 17, further comprising the steps of:
forming a plurality of first bumps on respective ones of the first die bonding pads, wherein the first wires are reverse bonded from the first corresponding pads on the top side of the base carrier to the first bumps on the first die bonding pads such that a plurality of stitch bonds are formed on the first bumps; and
forming second bumps on the stitch bonds, wherein the first and second bumps form a wall around the peripheral area of the first die to contain the adhesive material.

19. A method of making a stacked die package, comprising:
attaching a first IC die to a base carrier, the first die having a bottom surface and a top surface, the top surface having a central area and a peripheral area, the peripheral area including a plurality of first die bonding pads, wherein the bottom surface of the first die is attached to a top side of the base carrier;
forming a plurality of first bumps on respective ones of the first die bonding pads;
electrically connecting the first die to the base carrier by reverse bonding first wires from first pads on the top side of the base carrier to the first bumps on the first die bonding pads such that a plurality of stitch bonds are formed on the first bumps;
forming a plurality of second bumps on the stitch bonds;
forming a plurality of successive layers of an adhesive material on the central area of the top surface of the first die, wherein the first and second bumps form a wall around the peripheral area of the first die to contain the adhesive material;
attaching a bottom surface of a second die to the top surface of the first die with the adhesive material, the second die having a plurality of second die bonding pads located on a top surface thereof, wherein the successive layers of adhesive material maintain a predetermined spacing between the first die and the second die;
electrically connecting the second die to the base carrier by wirebonding second wires to the second die bonding pads and to corresponding second pads on the top side of the base carrier; and
encapsulating the first and second dice, the first and second wires, and at least a portion of the base carrier.

20. The method of making a stacked die package of claim 19, wherein the successive layers of adhesive material are formed by dispensing the adhesive material in multiple applications over the first die and wherein the adhesive material for each succeeding layer is dispensed when a preceding layer is substantially cured.
